(19) United States
(12) Patent Application Publication
(10) Pub. No.: US 2025/0338040 A1
(43) Pub. Date: Oct. 30, 2025

(54) IMAGE SENSOR

(71) Applicant: SAMSUNG ELECTRONICS CO., LTD., Suwon-si (KR)

(72) Inventors: Kyungmin KIM, Suwon-si (KR); Minsun KEEL, Suwon-si (KR); Youngtae JANG, Suwon-si (KR)

(73) Assignee: SAMSUNG ELECTRONICS CO., LTD., Suwon-si (KR)

(21) Appl. No.: 19/027,222

(22) Filed: Jan. 17, 2025

(30) Foreign Application Priority Data
Apr. 24, 2024 (KR) 10-2024-0054863
Aug. 16, 2024 (KR) 10-2024-0109563

(51) Int. Cl. H04N 25/78; H04N 25/51

(52) U.S. Cl. CPC H04N 25/78; H04N 25/51

(57) ABSTRACT

An image sensor includes a pixel array including pixels, and a peripheral circuit connected to the pixels. Each pixel includes a first photodiode, a second photodiode having a light-receiving area smaller than a light-receiving area of the first photodiode, and a pixel circuit connecting the first photodiode and the second photodiode to the peripheral circuit. The peripheral circuit obtains a first pixel signal by executing a first readout operation for each of the pixels after a first exposure time period, and obtains a second pixel signal by executing a second readout operation for a portion of the pixels after a second exposure time period that is shorter than the first exposure time period. The peripheral circuit generates first image data using the first pixel signal and second image data using the second pixel signal.

### CROSS-REFERENCE TO RELATED APPLICATIONS

This application claims priority to Korean Patent Application No. 10-2024-0109563 filed on Aug. 16, 2024 and to Korean Patent Application No. 10-2024-0054863 filed on Apr. 24, 2024 in the Korean Intellectual Property Office, the disclosures of each of which being incorporated by reference herein in their entireties.

### BACKGROUND

Example embodiments relate to an image sensor.

An image sensor may receive light and may generate an electric signal from the received light to thereby realize an image. Recently, as an image sensor is adopted in fields such as vehicle technologies, a method for accurately imaging various types of subjects has been suggested. As one method, various subjects may be accurately imaged by configuring image sensors differently, but this technical approach may require a great deal of space and a price may increase. Accordingly, various methods for accurately photographing various subjects having different characteristics using an image sensor have been suggested.

### SUMMARY

It is an aspect to provide an image sensor that improves a dynamic range and a signal-to-noise ratio by configuring a first readout operation executed after a first exposure time period and a second readout operation executed after a second first exposure time period differently in an image sensor having a structure including a first photodiode and a second photodiode including pixels each having different light-receiving areas.

According to an aspect of one or more example embodiments, there is provided an image sensor comprising a pixel array including a plurality of pixels arranged in a first direction and a second direction intersecting the first direction; and a peripheral circuit connected to the plurality of pixels through a plurality of row lines and a plurality of column lines, the peripheral circuit configured to drive the plurality of pixels. Each of the plurality of pixels includes a first photodiode, a second photodiode having a light-receiving area smaller than a light-receiving area of the first photodiode, and a pixel circuit connecting the first photodiode and the second photodiode to the peripheral circuit. The peripheral circuit is configured to obtain a first pixel signal by executing a first readout operation for each of the plurality of pixels after a first exposure time period, and to obtain a second pixel signal by executing a second readout operation for at least a portion of pixels of the plurality of pixels after a second exposure time period that is shorter than the first exposure time period, and the peripheral circuit is configured to generate first image data using the first pixel signal and second image data using the second pixel signal.

According to another aspect of one or more example embodiments, there is provided an image sensor comprising a plurality of pixels, each including a first photodiode, a second photodiode having a light-receiving area smaller than a light-receiving area of the first photodiode, and a pixel circuit connected to the first photodiode and the second photodiode; and a peripheral circuit configured to execute a first shutter operation, a first time period exposure operation, a first readout operation, a second shutter operation, a second time period exposure operation, and a second readout operation for each of the plurality of pixels in sequence. The first readout operation includes a plurality of first type readout operations executed in sequence, and the second readout operation includes a plurality of second type readout operations executed in sequence, and the peripheral circuit is configured to execute at least one of the plurality of second type readout operations differently from the plurality of first type readout operations.

According to yet another aspect of one or more example embodiments, there is provided an image sensor comprising a plurality of pixels, each including a first photodiode, a second photodiode having a light-receiving area smaller than a light-receiving area of the first photodiode, and a pixel circuit connected to the first photodiode and the second photodiode; and a peripheral circuit configured to drive the plurality of pixels. The pixel circuit is configured to output a signal by executing a plurality of first type readout operations after a first exposure time period, and to output a signal by executing a plurality of second type readout operations after a second exposure time period that is shorter than the first exposure time period, and in the plurality of second type readout operations, a number of times the pixel circuit outputs a signal corresponding to electric charges generated by the first photodiode is greater than a number of times the pixel circuit outputs a signal corresponding to electric charges generated by the second photodiode.

### BRIEF DESCRIPTION OF DRAWINGS

The above and other aspects will be more clearly understood from the following detailed description, taken in combination with the accompanying drawings, in which:

FIG. 1 is a block diagram illustrating an image sensor according to some example embodiments;

FIGS. 2 and 3 are diagram illustrating a pixel array structure of an image sensor according to some example embodiments;

FIG. 4 is a circuit diagram illustrating pixels included in an image sensor according to some example embodiments;

FIGS. 5 and 6 are diagrams illustrating operations of an image sensor according to some example embodiments;

FIGS. 7 to 15 are diagrams illustrating operations of an image sensor according to some example embodiments;

FIGS. 16 to 18 are diagrams illustrating operations of an image sensor according to some example embodiments;

FIG. 19 is a diagram illustrating operations of an image sensor according to some example embodiments;

FIGS. 20 and 21 are diagrams illustrating operations of an image sensor according to some example embodiments;

FIG. 22 is a diagram illustrating operations of an image sensor according to some example embodiments;

FIG. 23 is a diagram illustrating operations of an image sensor according to some example embodiments; and

FIG. 24 is a diagram illustrating operations of an image sensor according to some example embodiments.

### DETAILED DESCRIPTION

Hereinafter, various embodiments will be described as follows with reference to the accompanying drawings.

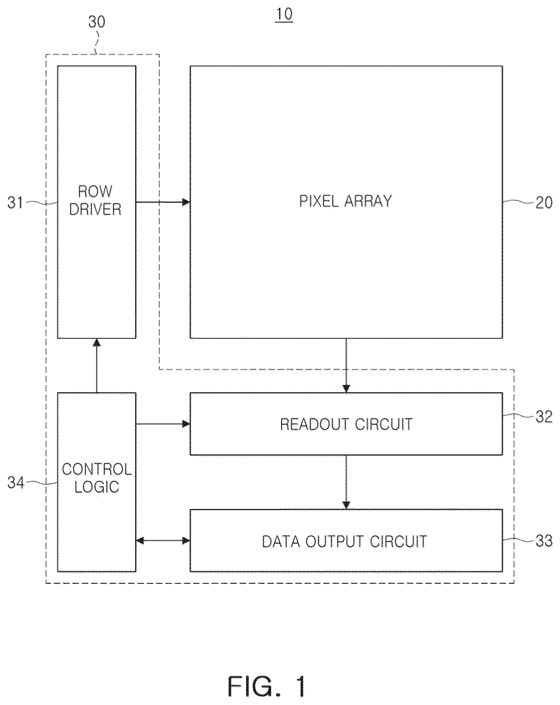

FIG. 1 is a block diagram illustrating an image sensor according to some example embodiments.

Referring to FIG. 1, an image sensor 10 may include a pixel array 20 and a peripheral circuit 30. The pixel array 20 may include a plurality of pixel regions arranged in an array along a plurality of rows and a plurality of columns. Each of the plurality of pixel regions may include a photoelectric conversion element configured to generate electric charges in response to light, and the photoelectric conversion element may be connected to a pixel circuit configured to generate and to output a signal corresponding to electric charges generated by the photoelectric conversion element.

A pixel may be implemented by the photoelectric conversion element and the pixel circuit. The photoelectric conversion element may include a photodiode formed of a semiconductor material, and/or an organic photodiode formed of an organic material. In an example embodiment, a pixel may include a first photodiode and a second photodiode having different light-receiving areas.

For example, the pixel circuit may include a plurality of transistors and a capacitor. In some example embodiments, the pixel circuit may include a plurality of capacitors. The capacitor may store electric charges excessively generated by the photodiode and may be connected to the photodiode through at least one transistor of the plurality of transistors. In an example embodiment, the capacitor may be a metal-insulator-metal (MIM) capacitor.

The peripheral circuit 30 may include circuits for controlling the pixel array 20. For example, the peripheral circuit 30 may include a row driver 31, a readout circuit 32, a data output circuit 33, and a control logic 34. The row driver 31 may drive the pixel array 20 in unit of row (ROW) lines. For example, the row driver 31 may input control signals for controlling turning on/off of each transistor included in the pixel circuit to the pixel array 20 in a unit of a row line.

Among the pixels, pixels disposed in a same position in the row direction (the horizontal direction in FIG. 1) may share the same column line. For example, pixels disposed in the same position in the column (COLUMN) direction (the vertical direction in FIG. 1) may be simultaneously selected by the row driver 31 and may output pixel signals through the column lines. In an example embodiment, the readout circuit 32 may simultaneously receive signals from the pixels selected by the row driver 31 through the column lines. For example, the readout circuit 32 may receive a reset voltage and a signal voltage from each pixel in sequence, and the signal voltage may be configured by reflecting electric charges generated by a photodiode of each pixel in a reset voltage.

The readout circuit 32 may include a plurality of correlated dual samplers and a plurality of counters, and the correlated dual samplers may be connected to each other through the pixels and the column lines. For example, a correlated dual sampler and a counter may be connected to a column line. The correlated dual samplers may read voltage signals from pixels connected to a row line selected by the row line select signal of the row driver 31 through the column lines. One of the input terminals of each of the correlated dual samplers may be connected to column lines, and the other input terminal may receive a lamp voltage.

An output terminal of each of the correlated dual samplers may be connected to counters, and the counters may generate a digital pixel signal by counting the time period during which an output of each of the correlated dual samplers is maintained at a specific voltage. For example, the counter may count the time period during which the lamp voltage input to the correlated dual sampler is greater than a voltage of the column line and may convert the output of the correlated dual sampler into a digital pixel signal. The data output circuit 33 may include a memory such as a latch or a buffer circuit for temporarily storing a digital pixel signal.

The control logic 34 may include a timing controller for controlling operation timings of the row driver 31, the readout circuit 32, and the data output circuit 33. According to an example embodiment, the control logic 34 may determine a data format output by the data output circuit 33, or may perform preprocessing of data to be output by the data output circuit 33.

In an example embodiment, the readout circuit 32 may execute a readout operation for each of a plurality of pixels two or more times. For example, when one of a plurality of row lines is selected, the readout circuit 32 may read a signal corresponding to electric charges generated by exposure of pixels, arranged along the selected row line, to light. In an example embodiment, the readout circuit 32 may read a signal corresponding to electric charges generated by pixels during a single exposure time period multiple times.

The readout circuit 32 may obtain signals from pixels under different operating conditions. For example, the readout circuit 32 may execute at least one readout operation under each of a condition in which a conversion gain of each pixel is relatively large and a condition in which a conversion gain of each pixel is relatively small. For example, in an example embodiment, the readout circuit 32 may execute a readout operation under the condition in which the conversion gain of each pixel is relatively large and may execute a readout operation under the condition in which the conversion gain of each pixel is relatively small. The conversion gain of each pixel may be varied depending on turning on/off of the transistor connected to the floating diffusion node of each of pixels.

As described above, each of the plurality of pixels may include a capacitor. During the exposure time period, electric charges generated by the photodiode and exceeding a full well capacity (FWC) of the photodiode may be transferred to the capacitor and stored, and the readout circuit 32 may execute a readout operation of obtaining a signal corresponding to electric charges stored in the capacitor. By generating an image using the signal obtained by the pixels under different operating conditions, the readout circuit 32 may expand a light intensity range which the image sensor 10 may represent, and may improve a dynamic range.

In an example embodiment, a first readout operation after a first exposure time period and a second readout operation after a second exposure time period that is shorter than the first exposure time period may be executed differently. By executing the first readout operation and the second readout operation in an optimized manner according to a length of the exposure time period, a signal-to-noise ratio, a dynamic range, or the like, of the first image data generated from electric charges generated in the first exposure time period and the second image data generated from electric charges generated by the second exposure time period may be improved.

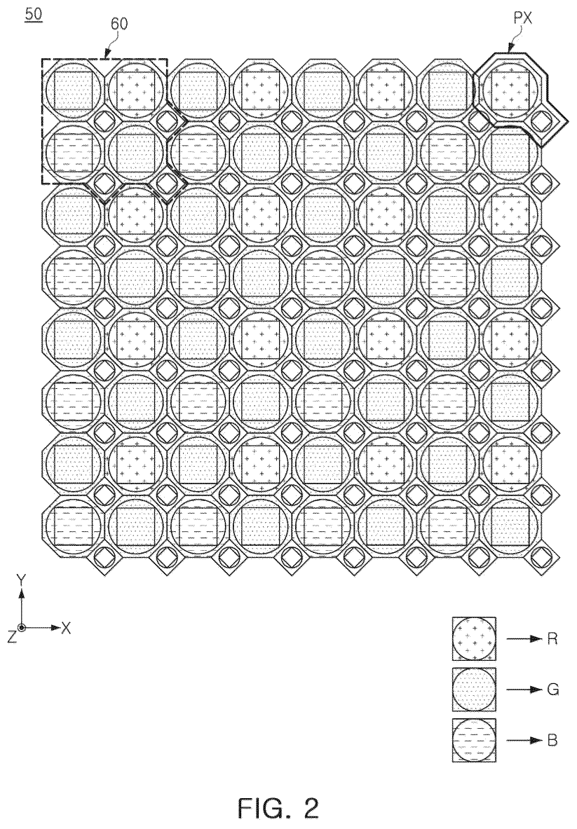

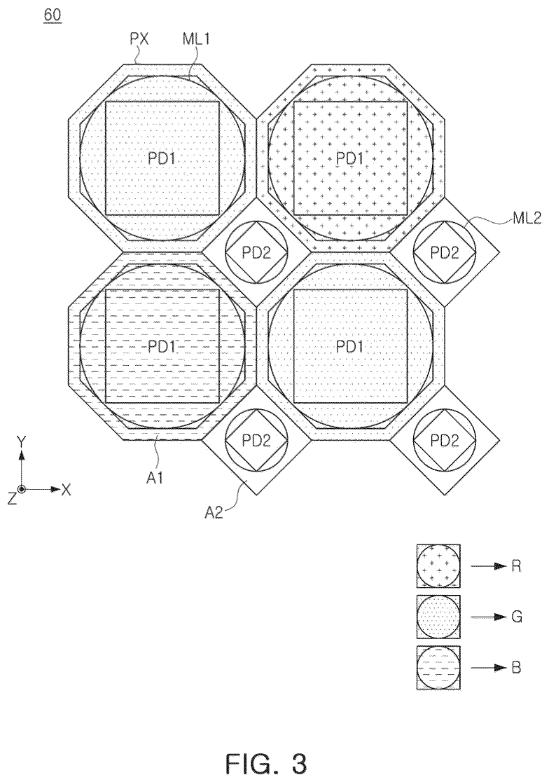

FIGS. 2 and 3 are diagram illustrating a pixel array structure of an image sensor according to some example embodiments. FIG. 3 may be an enlarged diagram of a portion of region 60 in FIG. 2.

Referring to FIG. 2, the pixel array 50 may include a plurality of pixels PX arranged in a first direction (X-axis direction) and a second direction (Y-axis direction). Each of the plurality of pixels PX may include a first photodiode PD1 and a second photodiode PD2. In an example embodiment, a light-receiving area of the first photodiode PD1 may be larger than a light-receiving area of the second photodiode PD2. Stated differently, the second photodiode PD2 may have a light-receiving area smaller than a light-receiving area of the first photodiode PD1. In an example embodiment illustrated in FIG. 2, in each of the plurality of pixels PX, the first photodiode PD1 and the second photodiode PD2 may be arranged in a diagonal direction that intersects both the first direction and the second direction.

Each of the plurality of pixels PX may include a color filter, and the color filter may transmit light corresponding to a wavelength of one of red, green, or blue colors. Each of the plurality of pixels PX may include one of a red color filter, a green color filter, or a blue color filter.

As described above, FIG. 3 may be an enlarged diagram of a portion of region 60 in FIG. 2. Referring to FIG. 3, among the plurality of pixels PX, four pixels PX disposed in a 2×2 array form may be disposed in a Bayer pattern. As illustrated in FIG. 3, among the four pixels PX disposed in a 2×2 array form, each of two pixels PX arranged in a diagonal direction may include a green color filter, and each of the other two pixels PX may include a red color filter or a blue color filter.

In an example embodiment illustrated in FIG. 2 and FIG. 3, each of the plurality of pixels PX may include a first micro-lens ML1 and a second micro-lens ML2. The first micro-lens ML1 may be disposed on the first photodiode PD1 in the first light-receiving region A1, and the second micro-lens ML2 may be disposed on the second photodiode PD2 in the second light-receiving region A2.

However, example embodiments are not limited to the arrangement illustrated in FIGS. 2 and 3. For example, four pixels PX disposed in a 2×2 array form in the first and second directions may be disposed in a tetra pattern including color filters of the same color. In some example embodiments, a portion of the plurality of pixels PX may omit a color filter, or may include a color filter transmitting light of a red, green, blue and other colors.

In each of the plurality of pixels PX, the first photodiode PD1 and the second photodiode PD2 may be connected to a column line through a single pixel circuit. The single pixel circuit may include a plurality of transistors and a capacitor. Electric charges generated during the exposure time period and exceeding the full well capacity (FWC) of the first photodiode PD1 and the second photodiode PD2 may be transferred to the capacitor and stored.

In an image sensor including a pixel array 50 according to an example embodiment, a readout operation may be executed differently depending on a length of the exposure time period. For example, when an image sensor is mounted on a means of transportation (e.g., a vehicle, etc.), the exposure time period may be configured to be longer than a predetermined time such that the image sensor may accurately recognize a flickering light source. However, when the exposure time period is configured to be relatively long as above, other subjects other than the flickering light source may not be accurately imaged. For example, in an obtained image of a subject moving at a fast speed, the shape of the subject may be distorted.

In an example embodiment, to address the above issue, first image data may be generated as a pixel signal corresponding to electric charges generated by a first exposure time period, and second image data may be generated as a pixel signal corresponding to electric charges generated by a second exposure time period that is shorter than the first exposure time period. Assuming that the image sensor is mounted on a means of transportation (e.g., a vehicle, etc.), a flickering light source may be accurately imaged using the first image data, and other subjects other than the flickering light source may be imaged without distortion using the second image data.

In an example embodiment, the first readout operation after the first exposure time period and the second readout operation after the second exposure time period may be executed differently. Due to the difference in the exposure time period, when the first readout operation and the second readout operation are executed with the same scheme, a signal-to-noise ratio, dynamic range, and the like, of the first image data and/or the second image data may be degraded. In an example embodiment, by executing the first readout operation with a first scheme optimized for a relatively long first exposure time period and executing the second readout operation with a second scheme optimized for a relatively short second exposure time period, each of the signal-to-noise ratio and the dynamic range of the first image data and the second image data may be improved.

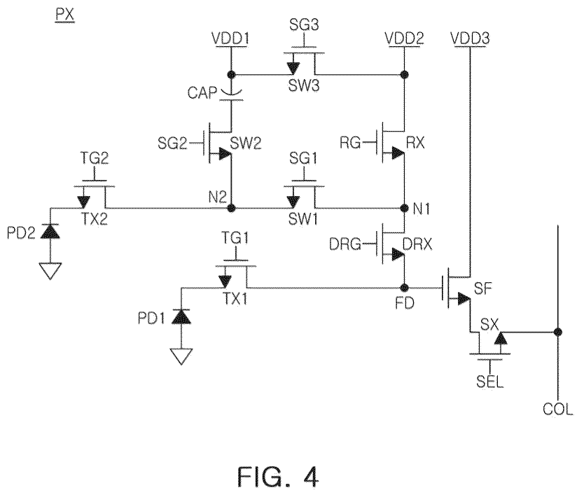

FIG. 4 is a circuit diagram illustrating pixels included in an image sensor according to some example embodiments.

Referring to FIG. 4, a pixel PX according to an example embodiment may include a first photodiode PD1, a second photodiode PD2, and a pixel circuit. In an example embodiment, the pixel circuit may include a floating diffusion node FD, a first transfer transistor TX1, a second transfer transistor TX2, a gain control transistor DRX, a capacitor

CAP, a first switch transistor SW1, a second switch transistor SW2, a third switch transistor SW3, a reset transistor RX, an amplification transistor SF, and a selection transistor SX. Control signals TG1, TG2, RG, SG1, SG2, SG3, DRG, and SEL for controlling a plurality of transistors included in the pixel circuit may be output by a row driver.

The floating diffusion node FD may be connected to the first photodiode PD1 through the first transfer transistor TX1, and when the first transfer transistor TX1 is turned on by the first transfer control signal TG1, electric charges of the first photodiode PD1 may be stored in the floating diffusion node FD. The floating diffusion node FD may be connected to the second photodiode PD2 through the second transfer transistor TX2, the first switch transistor SW1, and the gain control transistor DRX. In operation of transferring electric charges generated by the second photodiode PD2 to the floating diffusion node FD, the second transfer transistor TX2, the first switch transistor SW1, and the gain control transistor DRX may be turned on by the row driver.

The gain control transistor DRX may be connected between the floating diffusion node FD and a first node N1. When the gain control transistor DRX is turned on by the gain control signal DCG, a capacitance of the floating diffusion node FD may increase, such that a conversion gain of the pixel PX may decrease. Conversely, when the gain control transistor DRX is turned off, the conversion gain of the pixel PX may increase.

The first switch transistor SW1 may be connected between the first node N1 and a second node N2, and the capacitor CAP and the second switch transistor SW2 may be connected between the second node N2 and a first power node. The first power node may be configured to supply the first power voltage VDD1. Between the second node N2 and the first power node, the second switch transistor SW2 and the capacitor CAP may be connected to each other in series.

The reset transistor RX may be connected between the first node N1 and a second power node. The second power node may be configured to supply the second power voltage VDD2 and may be connected to a drain of the reset transistor RX. According to an example embodiment, the second power voltage VDD2 may be the same voltage as the first power voltage VDD1. In some example embodiments, the second power voltage VDD2 may be a voltage different from the first power voltage VDD1. In an example embodiment, the second power voltage VDD2 may be greater than the first power voltage VDD1. The third switch transistor SW3 may be connected between the first power node and the second power node.

A gate of the amplification transistor SF may be connected to the floating diffusion node FD, and the amplification transistor SF may be connected between a third power node and the selection transistor SX. The third power node may be configured to supply a third power voltage VDD3. According to an example embodiment, the third power voltage VDD3 may be equal to at least one of the first power voltage VDD1 or the second power voltage VDD2. In an example embodiment, the third power voltage VDD3 may be equal to the second power voltage VDD2 and may be greater than the first power voltage VDD1. In an example embodiment, the third power voltage VDD3 may be greater than the first power voltage VDD1 and the second power voltage VDD2.

The amplification transistor SF may operate as a source-follower amplifier and may generate a signal by amplifying a voltage of the floating diffusion node FD. The signal generated by the amplification transistor SF may be output to the column line COL by a turn-on operation of the selection transistor SX. The column line COL may be connected to one of the input terminals of the correlated dual sampler, and the correlated dual sampler may transmit a signal output to the column line COL and an output signal determined by the lamp voltage to the counter.

Operations of the pixel PX may include a shutter operation, an exposure operation, and a readout operation. In the shutter operation, electric charges of the floating diffusion node FD and the photodiode PD may be removed, and in the exposure operation, the photodiode PD may be exposed to light for an exposure time period and may generate electric charges. The exposure time period may be predetermined. In the readout operation, a voltage of the floating diffusion node FD may be amplified and may be output to the column line COL, and for example, a reset voltage and a signal voltage may be output to the column line COL. The reset voltage may be a voltage which may be output by the pixel circuit to the column line COL in a state in which the floating diffusion node FD is reset, and the signal voltage may be a voltage which may be output by the pixel circuit output to the column line COL in a state in which at least a portion of electric charges generated by the photodiode PD is stored in the floating diffusion node FD.

In an example embodiment, an operation in which a pixel circuit outputs a voltage to the column line COL after a single exposure time period may be executed two or more times. For example, a readout operation executed after a single exposure time period may include a plurality of sub-readout operations executed in sequence. In at least a portion of the plurality of sub-readout operations, conversion gains of the pixel PX may be configured differently.

In an example embodiment, the readout operation may include a relatively high conversion gain (HCG) sub-readout operation executed under a condition in which the pixel PX has a relatively large conversion gain, and a relatively low conversion gain (LCG) sub-readout operation executed under a condition in which the pixel PX has a relatively small conversion gain. In an example embodiment, the readout operation may include a lateral overflow integrated capacitor (LOFIC) readout operation of reading a voltage corresponding to electric charges that are generated by the FWC or more than the FWC of photodiodes PD1 and PD2 during the exposure time period and that are stored in the capacitor CAP by overflow.

As described above, by executing two or more sub-readout operations after a single exposure time period, a signal-to-noise ratio and a dynamic range of the image sensor may be improved. In an example embodiment, depending on a length of the exposure time period, the number of sub-readout operations executed after the exposure time period and a method of executing each sub-readout operation may be varied. By selecting and combining sub-readout operations in an optimized manner depending on a length of the exposure time period and executing the operations, a signal-to-noise ratio and a dynamic range of image data generated by the image sensor may be improved regardless of a length of the exposure time period.

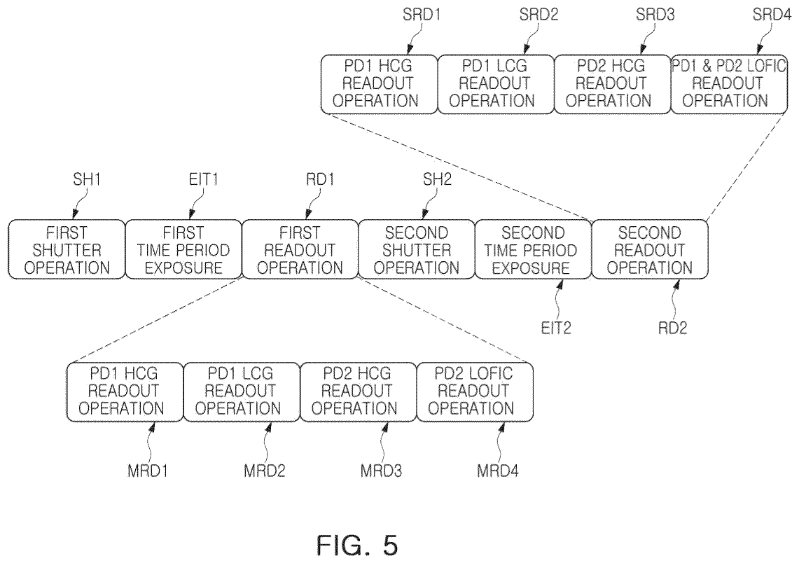

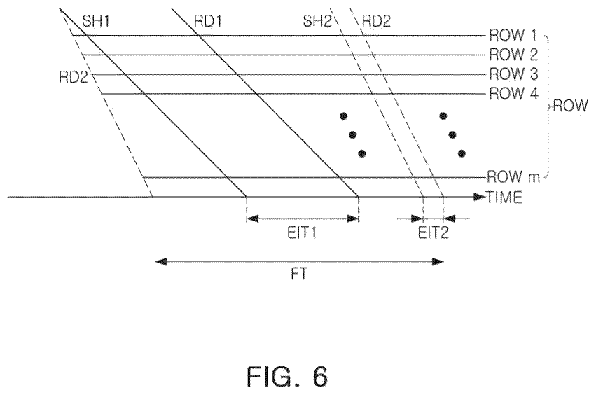

FIGS. 5 and 6 are diagrams illustrating operation of an image sensor according to some example embodiments.

FIG. 5 may be a diagram illustrating operation of a pixel included in an image sensor according to an example embodiment. The pixel may include a first photodiode PD1, a second photodiode PD2 having a light-receiving area smaller than a light-receiving area of the first photodiode PD1, and a pixel circuit. In an example embodiment, pixels included in the pixel array may be arranged in a row direction and a column direction, and may be connected to a row driver in the row direction and may be connected to a readout circuit in the column direction. The row driver may simultaneously drive the pixels arranged in the row direction, and accordingly, the operation illustrated in FIG. 5 may be simultaneously executed in two or more pixels arranged in the row direction. For example, in some embodiments, the pixel may be the pixel PX described above with reference to FIGS. 1-4.

The operation of the pixel may include a first shutter operation SH1, a first time period exposure EIT1, a first readout operation RD1, a second shutter operation SH2, a second time period exposure EIT2, and a second readout operation RD2. The first time period exposure EIT1 and the second time period exposure EIT2 may be different, and for example, the first time period exposure EIT1 may be longer than the second time period exposure EIT2.

The first image data may be generated by each of pixels executing the first shutter operation SH1, the first time period exposure EIT1, and the first readout operation RD1, and the second image data may be generated by each of pixels executing the second shutter operation SH2, the second time period exposure EIT2, and the second readout operation RD2. When the image sensor is mounted on a means of transportation (e.g., a vehicle, etc.), the first image data and the second image data may be output in each of the repeated frame periods, or the first image data and the second image data may be output in a portion of the frame periods.

For example, the first image data may be image data for accurately capturing a flickering light source, and the second image data may be image data for accurately capturing a subject without distortion. According to an example embodiment, resolution of the first image data may be higher than resolution of the second image data. According to an example embodiment, a frame rate of the first image data may be lower than a frame rate of the second image data, and a frame period in which the first image data is output in frame unit may be longer than the frame period in which the second image data is output in frame unit.

In each of the first shutter operation SH1 and the second shutter operation SH2, a reset operation may be executed to remove electric charges of the photodiode and floating diffusion node of the pixel. For example, in the first shutter operation SH1 and the second shutter operation SH2, the photodiode and the floating diffusion node may be electrically connected to the power node.

During the first time period exposure EIT1 and the second time period exposure EIT2, the photodiode may be exposed to light and may generate electric charges. For example, in each of the first time period exposure EIT1 and the second time period exposure EIT2, the transfer transistor may be turned off, and the photodiode and the floating diffusion node may be electrically isolated from each other. Accordingly, electric charges generated by the photodiode may not move to the floating diffusion node.

However, in an environment in which intensity of light entering the photodiode is extremely strong, electric charges exceeding the FWC of the photodiode may be generated. In this case, electric charges generated excessively in the photodiode causes a voltage drop at a node at which the photodiode and the transfer transistor are connected to each other, which may cause leakage through the transfer transistor, and electric charges generated by the photodiode may move to the floating diffusion node.

In an example embodiment, the pixel may be configured such that electric charges transferred from the photodiode to the floating diffusion node during the first time period exposure EIT1 and/or the second time period exposure EIT2 may move to the capacitor connected to the floating diffusion node. Accordingly, in an environment in which intensity of light is extremely strong, electric charges generated exceeding the FWC of the photodiode may pass through the floating diffusion node and may be stored in the capacitor. Thereafter, in at least one of the first or the second readout operations, the pixel circuit may output a voltage corresponding to electric charges stored in the capacitor. Accordingly, image data in which a subject is accurately represented may be generated even in an environment with extremely high illumination, and the dynamic range of the image sensor may be improved.

FIG. 6 may be a diagram illustrating operation of an image sensor during a single frame period FT in which first image data and second image data are output. Referring to FIG. 6, pixels may be selected along row lines ROW in a pixel array of the image sensor, and a first shutter operation SH1 may be executed. The first shutter operation SH1 may be executed in sequence from pixels of a row line in which the second readout operation RD2 in the previous frame period has ended. As described above, when the first shutter operation SH1 is executed in pixels arranged along one of the row lines ROW, a reset operation may be executed in which electric charges of the floating diffusion node and photodiode of the pixels are removed.

For example, when the first shutter operation SH1 is completed for pixels arranged in the first row line ROW1, the pixels may be exposed to light during the first time period exposure EIT1. The first time period exposure EIT1 may be defined as the time period from when the first shutter operation SH1 is completed for the pixels in the first row line ROW1 to when the first readout operation RD1 is executed for the pixels in the first row line ROW1. While the pixels arranged in the first row line ROW1 are exposed to light, the first shutter operation SH1 may be executed in sequence for each of the other row lines ROW2-ROWm.

The first readout operation RD1 may be executed for pixels for which the first time period exposure EIT1 has elapsed. In an example embodiment, the first readout operation RD1 may include a plurality of sub-readout operations executed in sequence, and for example, in each of the plurality of sub-readout operations, the pixel may output a signal using a different scheme.

When the first readout operation RD1 is completed for pixels connected to the row lines ROW, the second shutter operation SH2 may be started. Similarly to the first shutter operation SH1, the second shutter operation SH2 may include an operation for selecting pixels along the row lines ROW and resetting electric charges of the floating diffusion node and the photodiode. The pixels for which the second shutter operation SH2 has been completed may be exposed to light for the second time period exposure EIT2. The second time period exposure EIT2 may be shorter than the first time period exposure EIT1. For the pixels for which the second time period exposure EIT2 has been completed, the second readout operation RD2 may be executed.

As described above, the first image data generated based on the signal output by the pixels in the first readout operation RD1 and the second image data generated based on the signal output by the pixels in the second readout operation RD2 may be different from each other. For example, the first image data and the second image data may be different from each other in terms of resolution, color information, and the like.

Since the first time period exposure EIT1 and the second time period exposure EIT2 are different, when the first readout operation RD1 and the second readout operation RD2 are executed with the same scheme, a signal-to-noise ratio, a dynamic range, and the like, of the first image data and/or the second image data may deteriorate. In an example embodiment, the first readout operation RD1 and the second readout operation RD2 may be executed in different manners, thereby improving a signal-to-noise ratio, a dynamic range, and the like, of each of the first image data and the second image data.

In an example embodiment illustrated in FIG. 5, the first readout operation RD1 may include a plurality of main readout operations MRD, and the second readout operation RD2 may include a plurality of sub-readout operations SRD. For example, the plurality of main readout operations MRD may be defined as a plurality of first type readout operations, or a plurality of long exposure readout operations, and the plurality of sub-readout operations SRD may be defined as a plurality of second type readout operations, or a plurality of short exposure readout operations. In an example embodiment, the plurality of main readout operations MRD may include a first main readout operation MRD1, a second main readout operation MRD2, a third main readout operation MRD3, and a fourth main readout operation MRD4. In an example embodiment, the plurality of sub-readout operations SRD may include a first sub-readout operation SRD1, a second sub-readout operation SRD2, a third sub-readout operation SRD3, and a fourth sub-readout operation SRD4. Referring to FIG. 5, each of the first main readout operation MRD1 and the first sub-readout operation SRD1 may be an operation of reading a pixel signal corresponding to electric charges generated by the first photodiode PD1 under the condition in which the pixel has a relatively high conversion gain.

The second main readout operation MRD2 and the second sub-readout operation SRD2 may be operations for reading a pixel signal corresponding to electric charges generated by the first photodiode PD1 under the condition in which the pixel has a relatively low conversion gain. The third main readout operation MRD3 and the third sub-readout operation SRD3 may be operations of reading a pixel signal corresponding to electric charges generated by the second photodiode PD2 under the condition in which the pixel has a relatively high conversion gain. In an example embodiment illustrated in FIG. 5, the first to third main readout operations MRD1-MRD3 may be executed in the same manner as the first to third sub-readout operations SRD1-SRD3.

The fourth main readout operation MRD4 and the fourth sub-readout operation SRD4 may be executed in different manners. Referring to FIG. 5, the fourth main readout operation MRD4 may be an operation of reading a pixel signal corresponding to electric charges generated to exceed a FWC of the second photodiode PD2 and stored in a capacitor. The fourth sub-readout operation SRD4 may be an operation of reading a pixel signal corresponding to electric charges generated to exceed the FWC of each of the first photodiode PD1 and the second photodiode PD2 and stored in the capacitor.

By configuring the second readout operation RD2 after the relatively short second time period exposure EIT2 differently from the first readout operation RD1 after the relatively long first time period exposure EIT1, a signal-to-noise ratio and a dynamic range of the second image data generated by the second readout operation RD2 may be improved. For example, by reading the pixel signal corresponding to electric charges generated to exceed the FWC of each of the first photodiode PD1 and the second photodiode PD2 in the fourth sub-readout operation SRD4, the pixel signal in a low-illuminance region may be assured instead of the unnecessary high-illuminance region. Accordingly, the signal-to-noise ratio may be improved in the illuminance region necessary for representing a subject to be imaged with the second image data. In an example embodiment illustrated in FIG. 5, the fourth sub-readout operation SRD4, executed last in the second readout operation RD2, may be executed in a different manner from each of the main readout operations MRD1-MRD4.

In an example embodiment, in executing the plurality of sub-readout operations SRD1-SRD4, a number of times a pixel outputs a signal corresponding to electric charges generated by a first photodiode PD1 may be greater than a number of times a pixel outputs a signal corresponding to electric charges generated by a second photodiode PD2. Referring to FIG. 5, in executing the plurality of sub-readout operations SRD1-SRD4, a signal corresponding to electric charges generated by a first photodiode PD1 may be output from the first, second and fourth sub-readout operations SRD1, SRD2, and SRD4, and a signal corresponding to electric charges generated by a second photodiode PD2 may be output from the third and fourth sub-readout operations SRD3 and SRD4.

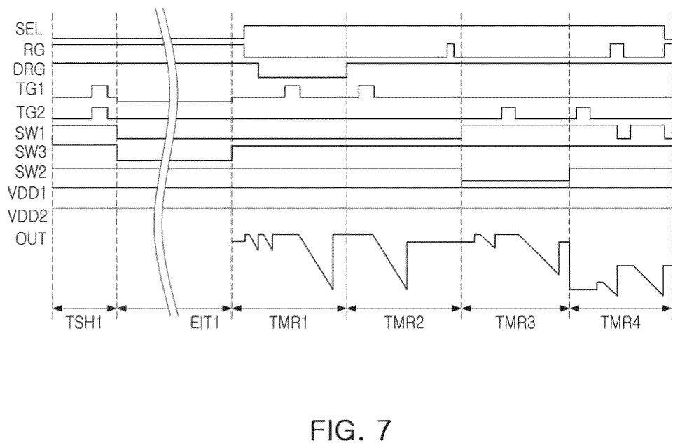

FIGS. 7 to 15 are diagrams illustrating operations of an image sensor according to some example embodiments.

Each pixel PX included in the image sensor described with reference to FIGS. 7 to 15 may have a structure similar to the aforementioned example embodiments described with reference to FIGS. 1-4. FIG. 7 may be a timing diagram illustrating the first shutter operation SH1, the first time period exposure EIT1 and the first readout operation RD1 described with reference to FIG. 5. In the operation of the pixel PX described with reference to FIGS. 7 to 15, the turning on/off of each of transistors TX1, TX2, RX, SW1, SW2, SW3, DRX, and SX included in the pixel PX may be determined by control signals TG1, TG2, RG, SG1, SG2, SG3, DRG, and SEL output by the row driver.

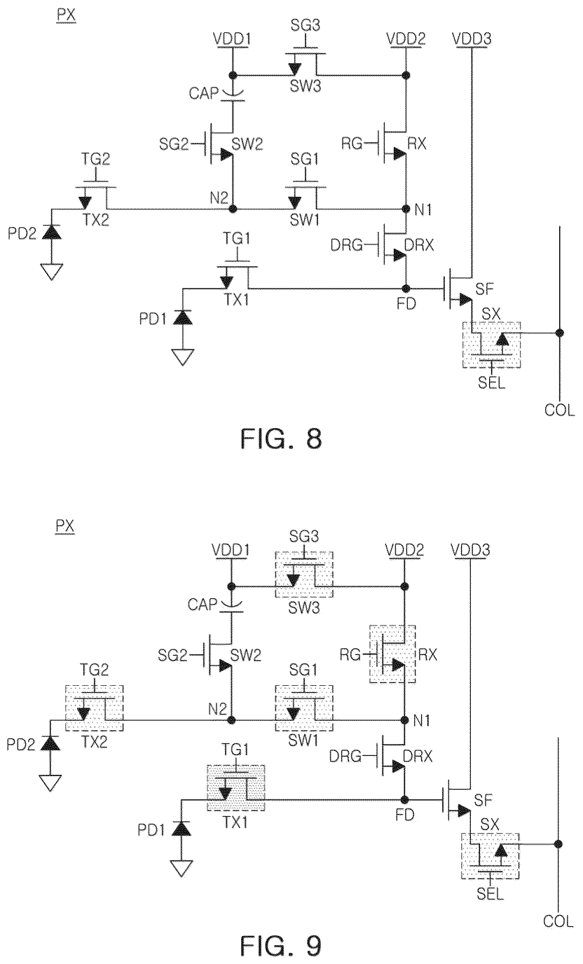

FIG. 8 may be a diagram illustrating operation of the pixel PX during a first shutter operation time period TSH1 shown in FIG. 7. During the first shutter operation time period TSH1, as illustrated in FIGS. 7 and 8, the first transfer transistor TX1, the second transfer transistor TX2, the first switch transistor SW1, the second switch transistor SW2, the third switch transistor SW3, the reset transistor RX, and the gain control transistor DRX may be turned on, and the selection transistor SX may be turned off. Accordingly, electric charges of the first photodiode PD1, the second photodiode PD2, the floating diffusion node FD, and the capacitor CAP may be removed by the first power voltage VDD1 and the second power voltage VDD2.

Referring to FIGS. 7 and 9, during the first time period exposure EIT1, the first switch transistor SW1 and the second switch transistor SW2 may be turned on, and the other transistors TX1, TX2, SW3, RX, DRX, and SX may be turned off. The first photodiode PD1 and the second photodiode PD2 may generate electric charges in response to light, and the generated electric charges may remain in the first photodiode PD1 and the second photodiode PD2. However, in an environment in which extremely strong light is input, electric charges may be generated by the FWC or more than the FWC of the first photodiode PD1 and the second photodiode PD2. Hereinafter, for ease of description, the electric charge generated to exceed the FWC of each of the first photodiode PD1 and the second photodiode PD2 may be defined as excessive electric charges.

For example, when the excessive electric charges are generated by the second photodiode PD2, a voltage of the node at which the second transfer transistor TX2 and the second photodiode PD2 are connected to each other, for example, the source voltage of the second transfer transistor TX2, may decrease due to electric charges. Accordingly, even though the second transfer control signal TG2 input to the gate of the second transfer transistor TX2 is maintained at a voltage corresponding to a logic row, a path for electric charge movement may be formed through the channel of the second transfer transistor TX2, and the excessive electric charges of the second photodiode PD2 may move to the second node N2.

In an example embodiment, the second switch transistor SW2 connected to the capacitor CAP may be turned on during the first time period exposure EIT1 such that the excessive electric charges moved to the second node N2 may move to and be stored in the capacitor CAP. The first switch transistor SW1 may be turned off such that the excessive electric charges may not move to the floating diffusion node FD. According to an example embodiment, the gain control transistor DRX may be turned off together with the first switch transistor SW1 during the first time period exposure EIT1.

Referring to FIG. 7 and FIG. 9, during the first time period exposure EIT1, the first transfer control signal TG1 may be configured to have a voltage lower than a voltage of the second transfer control signal TG2. The first transfer transistor TX1 may be more strongly turned off than the second transfer transistor TX2, and a path for electric charges movement due to the excessive electric charge generated by the first photodiode PD1 may not be generated by the first transfer transistor TX1. Accordingly, the excessive electric charges generated by the second photodiode PD2 may be predominantly stored in the capacitor CAP.

In an example embodiment illustrated in FIG. 7, the pixel PX may execute the first readout operation RD1 after the first time period exposure EIT1 has elapsed. As described above with reference to FIG. 5, the first readout operation RD1 may include a plurality of main readout operations MRD1-MRD4.

Referring to FIG. 7, during the first main readout time period TMR1, the selection transistor SX may be turned on by the selection control signal SEL, and the reset transistor RX may be turned off. When the selection transistor SX is turned on, the amplification transistor SF may amplify a voltage of the floating diffusion node FD and may output the reset voltage.

Referring to FIG. 7, the reset voltage may be output twice. The first reset voltage may be output in a state in which the gain control transistor DRX is turned on, and the second reset voltage may be output in a state in which the gain control transistor DRX is turned off. The first reset voltage may be a reset voltage output under the condition in which the pixel PX has a relatively low conversion gain, and the second reset voltage may be a reset voltage output under the condition in which the pixel PX has a relatively high conversion gain.

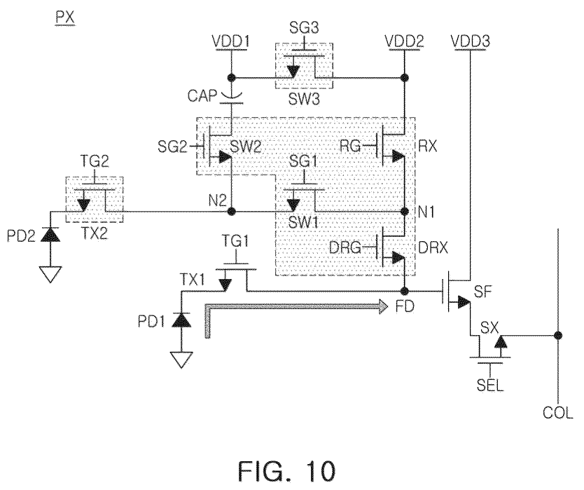

When the reset voltage is output, as illustrated in FIG. 7 and FIG. 10, the first transfer transistor TX1 may be turned on, and electric charges of the first photodiode PD1 may move to the floating diffusion node FD. The amplification transistor SF may output a signal voltage obtained by amplifying the voltage of the floating diffusion node FD to the column line COL. The readout circuit connected to the column line COL may derive the first pixel signal from the difference between the reset voltage and the signal voltage.

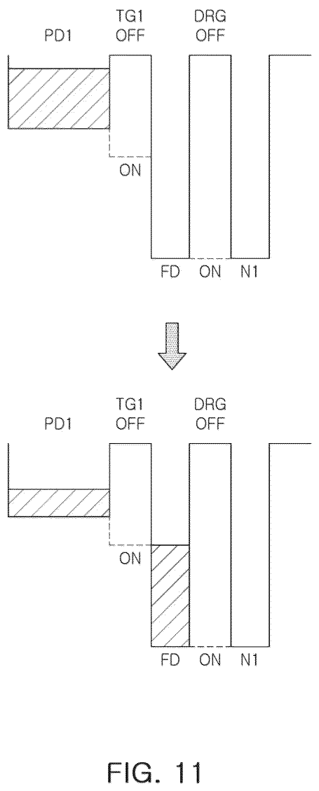

The first pixel signal may be a signal for covering a relatively low first range of illumination. Referring to FIGS. 10 and 11, while the pixel PX outputs a signal voltage to the column line COL, the gain control transistor DRX may be turned off. Accordingly, capacitance of the floating diffusion node FD may be maintained sufficiently low, and the signal voltage may be output under the condition in which the pixel PX has a relatively high conversion gain.

Referring to FIG. 11, the first transfer transistor TX1 may be turned on by the first transfer control signal TG1, such that a portion of electric charges of the first photodiode PD1 may be transferred to the floating diffusion node FD. Since the gain control transistor DRX is turned off, the first node N1 and the floating diffusion node FD are separated from each other, such that electric charges may be stored in the floating diffusion node FD having a relatively low capacitance, and the signal voltage may be output to the column line COL under the condition of relatively high conversion gain.

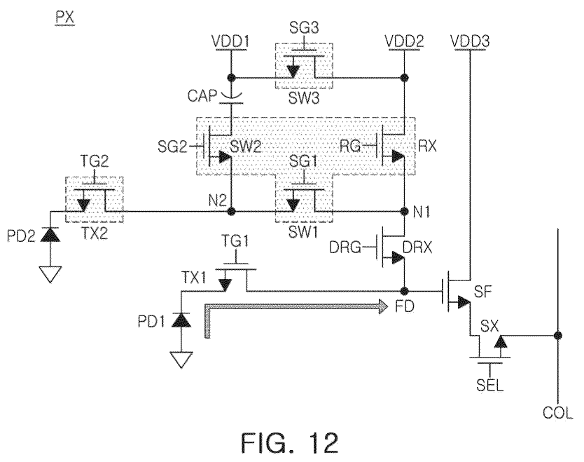

Thereafter, referring to FIG. 7 and FIG. 12, during the second main readout time period TMR2, the gain control transistor DRX may be turned on and the first node N1 may be connected to the floating diffusion node FD. Accordingly, during the second main readout time period TMR2, capacitance of the floating diffusion node FD may be added to capacitance of the gain control transistor DRX and capacitance of the first node N1, such that the pixel PX may output a signal under a relatively low conversion gain condition.

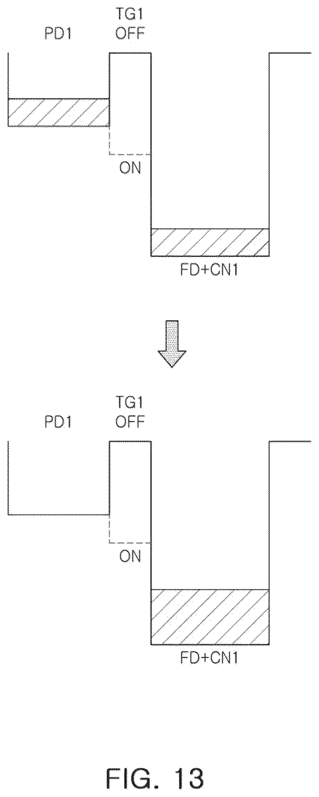

While the gain control transistor DRX is turned on and capacitance of the floating diffusion node FD is increased, the first transfer transistor TX1 may be turned on such that the residual electric charge remaining in the first photodiode PD1 may be transferred to the floating diffusion node FD. Referring to FIG. 13, the residual electric charge remaining in the first photodiode PD1, which may not move to the floating diffusion node FD during the first main readout time period TMR1, may move to the floating diffusion node FD when the first transfer transistor TX1 is turned on during the second main readout time period TMR2.

As illustrated in FIG. 13, capacitance of the floating diffusion node FD may be a sum of capacitance of the floating diffusion node FD and capacitance CN1 of the first node N1 and the gain control transistor DRX. As such, the signal voltage may be output to the column line COL during the second main readout time period TMR2 under the condition in which the pixel PX has a relatively low conversion gain.

Since at least a portion of electric charges of the first photodiode PD1 have already moved to the floating diffusion node FD during the first main readout time period TMR1, the reset voltage may not be output before the signal voltage during the second main readout time period TMR2. In an example embodiment, the reset voltage may be output twice during the first main readout time period TMR1 as described above, and the first reset voltage may be a reset voltage output under the condition in which the pixel PX has low conversion gain. The readout circuit may generate the second pixel signal under the low conversion gain condition using a difference between the first reset voltage output by the pixel PX during the first main readout time period TMR1 and the signal voltage output by the pixel PX during the second main readout time period TMR2. The second pixel signal may be a signal for covering the illumination of the second range higher than the first range.

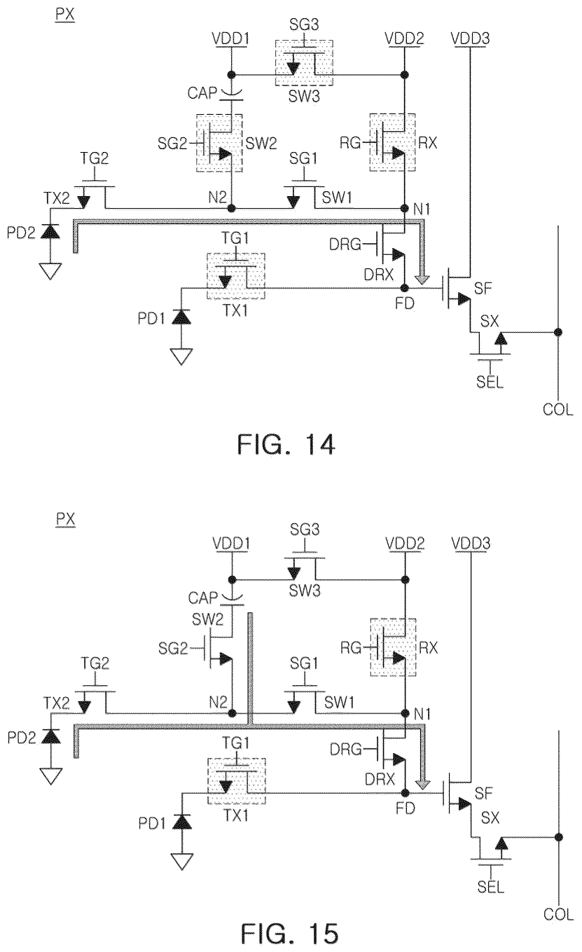

Referring to FIG. 7, the reset transistor RX may be turned on before termination of the second main readout time period TMR2 or after termination of the second main readout time period TMR2, such that the floating diffusion node FD may be reset. Accordingly, in the third main readout time period TMR3, the pixel PX may output the reset voltage. When the reset voltage is output, the second transfer transistor TX2, the first switch transistor SW1, and the gain control transistor DRX may be turned on as illustrated in FIG. 7 and FIG. 14.

Accordingly, electric charges of the second photodiode PD2 may move to the floating diffusion node FD, and the amplification transistor SF may amplify the voltage of the floating diffusion node FD and may output a signal voltage. The readout circuit may generate a third pixel signal using the difference between the reset voltage output by the pixel PX in the third main readout time period TMR3 and the signal voltage. The third pixel signal may be a signal to cover a third range of illuminance higher than that of the second range.

FIG. 15 may be a diagram illustrating operation of pixel PX in a fourth main readout time period TMR4. Referring to FIG. 7 and FIG. 15, during the fourth main readout time period TMR4, first to third switch transistors SW1-SW3, gain control transistor DRX, and second transfer transistor TX2 may be turned on. Since the first to third switch transistors SW1-SW3 and the gain control transistor DRX are turned on, electric charges stored in the capacitor CAP may be transferred to the floating diffusion node FD. Through a column line COL, a signal voltage corresponding to electric charges stored in the capacitor CAP may be output.

When the signal voltage is output, the row driver may turn on the reset transistor RX. Accordingly, a reset operation in which electric charges of floating diffusion node FD is removed is executed, and a reset voltage may be output through the column line COL. In the fourth main readout time period TMR4, the signal voltage may be output before the reset voltage. The readout circuit may generate the fourth pixel signal using the difference between the reset voltage output by the pixel PX and the signal voltage. The fourth pixel signal may be a signal for covering the fourth range of illumination higher than the third range of illumination.

As described above, the capacitor CAP may store an excessive electric charge generated to exceed the FWC of the second photodiode PD2 during the exposure time period. Electric charges may be stored in the capacitor CAP under the condition in which strong light configured to generate electric charge exceeding the FWC of the second photodiode PD2 enters the pixel PX. Accordingly, extremely high illumination may be covered using the fourth pixel signal generated from electric charges stored in the capacitor CAP.

When the first shutter operation SH1, the first time period exposure EIT1 and the first readout operation RD1 are completed as in an example embodiment described with reference to FIGS. 7 to 15, the pixel PX may execute the second shutter operation SH2, the second time period exposure EIT2 and the second readout operation RD2. The second time period exposure EIT2 may be shorter than the first time period exposure EIT1.

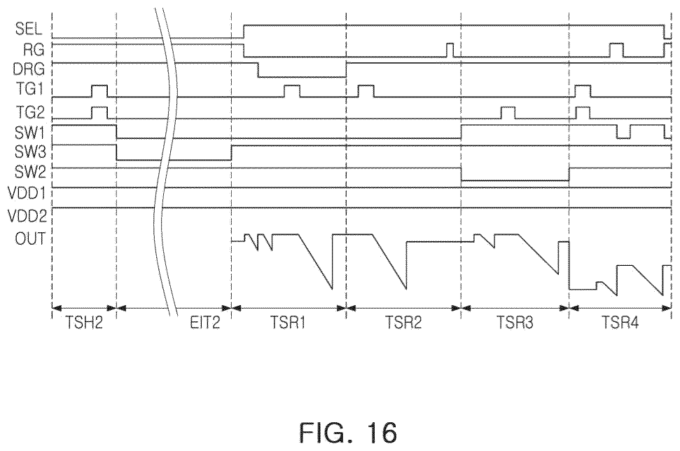

For example, the first image data may be generated from the signal output by the pixel PX in the first readout operation RD1, and the second image data may be generated from the signal output by the pixel PX in the second readout operation RD2. The first image data and the second image data may have different characteristics and may be used for different purposes. For example, the first image data may be used to accurately capture a flickering light source, and the second image data may be used to accurately capture a subject without distortion. Hereinafter, the second shutter operation SH2, the second time period exposure EIT2, and the second readout operation RD2 of the pixel PX will be described with reference to FIGS. 16 to 18.

FIGS. 16 to 18 are diagrams illustrating operation of an image sensor according to some example embodiments.

Each of the pixels PX included in the image sensor described with reference to FIGS. 16 to 18 may have a structure similar to the aforementioned example embodiment described with reference to FIGS. 1-4. FIG. 16 may be a timing diagram illustrating a second shutter operation SH2, a second time period exposure EIT2, and a second readout operation RD2. In the operation of the pixel PX described with reference to FIGS. 16 to 18, the turning on/off of each of the transistors TX1, TX2, RX, SW1, SW2, SW3, DRX, and SX included in the pixel PX may be determined by the control signals TG1, TG2, RG, SG1, SG2, SG3, DRG, and SEL output by the row driver.

Referring to FIG. 16, the second shutter operation SH2 may be executed in the same manner as the first shutter operation SH1 described with reference to FIGS. 7 and 8. As illustrated in FIG. 16, in the second shutter operation time period TSH2, the first switch transistor SW1, the second switch transistor SW2, the third switch transistor SW3, the reset transistor RX, and the gain control transistor DRX may be turned on, and the selection transistor SX may be turned off. When the first transfer transistor TX1 and the second transfer transistor TX2 are turned on, electric charges of the first photodiode PD1, the second photodiode PD2, the floating diffusion node FD, and the capacitor CAP may be removed by the first power voltage VDD1 and the second power voltage VDD2.

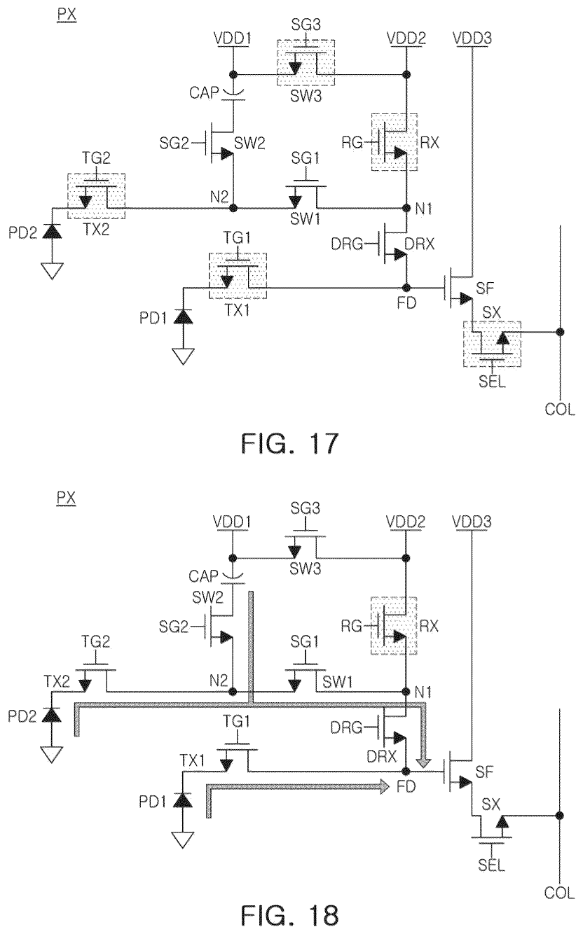

As illustrated in FIG. 17, during the second time period exposure EIT2, in the pixel PX, the first switch transistor SW1, the second switch transistor SW2, and the gain control transistor DRX may be turned on, and the other transistors TX1, TX2, SW3, RX, and SX may be turned off. The first photodiode PD1 and the second photodiode PD2 may generate electric charges in response to light. In an environment in which extremely strong light is input, excessive electric charges may be generated by the FWC or more that the FWC of the first photodiode PD1 and the second photodiode PD2.

During the second time period exposure EIT2, excessive electric charges generated by each of the first photodiode PD1 and the second photodiode PD2 may be stored in the capacitor CAP. The gain control transistor DRX and the first switch transistor SW1 may be turned on to provide electric charges path through which the excessive electric charge of the first photodiode PD1 may move to the capacitor CAP. The excessive electric charge of the first photodiode PD1 may move to the capacitor CAP through the first node N1 and the second node N2, and the excessive electric charge of the second photodiode PD2 may move to the capacitor CAP through the second node N2. Differently from the first time period exposure EIT1, the first transfer control signal TG1 and the second transfer control signal TG2 may be configured to have the same voltage.

The second readout operation RD2 executed after the second time period exposure EIT2 may be executed in a different manner from the first readout operation RD1 executed after the first time period exposure EIT1. As described above with reference to FIG. 5, the second readout operation RD2 may include a plurality of sub-readout operations SRD1-SRD4, and the first to third sub-readout operations SRD1-SRD3 may be executed in the same manner as the first to third main readout operations MRD1-MRD3. Accordingly, the operation of the pixel PX in each of the first to third sub-readout time periods TSR1-TSR3 may be the same as the operation of the pixel PX in each of the first to third main readout time periods TMR1-TMR3 described above.

FIG. 18 may be a diagram illustrating the operation of the pixel PX in the fourth sub-readout time period TSR4. Referring to FIGS. 16 and 18, during the fourth sub-readout time period TSR4, the first to third switch transistors SW1-SW3, the gain control transistor DRX, the first transfer transistor TX1 and the second transfer transistor TX2 may be turned on. Since the first to third switch transistors SW1-SW3 and the gain control transistor DRX are turned on, electric charges stored in the capacitor CAP may move to the floating diffusion node FD. A signal voltage corresponding to electric charges stored in the capacitor CAP may be output through the column line COL.

When the signal voltage is output, the row driver may turn on the reset transistor RX. Accordingly, a reset operation of removing electric charges of the floating diffusion node FD may be executed, and the reset voltage may be output through the column line COL. During the fourth sub-readout time period TSR4, the signal voltage may be output before the reset voltage. The readout circuit may use the difference between the reset voltage output by the pixel PX and the signal voltage and may generate the pixel signal.

As described above, the capacitor CAP may store excessive electric charge generated to exceed the FWC of the first photodiode PD1 and the second photodiode PD2 during the exposure time period. Electric charges may be stored in the capacitor CAP under the condition in which strong light configured to generate electric charges exceeding the FWC of the first photodiode PD1 and the second photodiode PD2 enters the pixel PX.

During the second time period exposure EIT2, electric charges generated to exceed the FWC of each of the first photodiode PD1 and the second photodiode PD2 may be stored in the capacitor CAP, and the pixel signal corresponding to electric charges stored in the capacitor CAP may be read out during the fourth sub-readout time period TSR4. Accordingly, the signal-to-noise ratio of the pixel signal may be improved in the illuminance region used to clearly capture a subject instead of the high illuminance region.

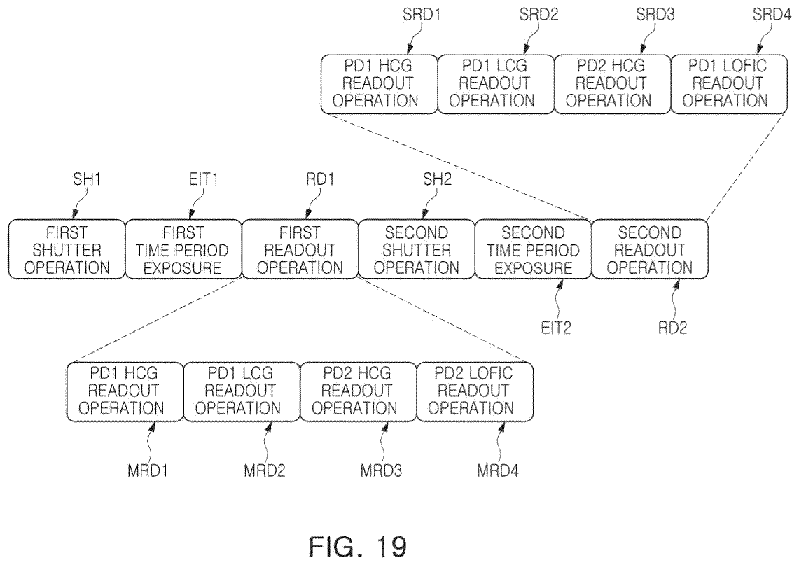

FIG. 19 is a diagram illustrating operations of an image sensor according to some example embodiments.

FIG. 19 may be a diagram illustrating operations of a pixel included in an image sensor according to an example embodiment. In an example embodiment, pixels included in a pixel array may be arranged in the row direction and the column direction, may be connected to a row driver in the row direction, and may be connected to a readout circuit in the column direction. The operations illustrated in FIG. 19 may be executed simultaneously in two or more pixels arranged in the row direction.

The operations of the pixel may include a first shutter operation SH1, a first time period exposure EIT1, a first readout operation RD1, a second shutter operation SH2, a second time period exposure EIT2, and a second readout operation RD2. The first time period exposure EIT1 and the second time period exposure EIT2 may be different, and for example, the first time period exposure EIT1 may be longer than the second time period exposure EIT2. First image data may be generated by each pixel executing the first shutter operation SH1, the first time period exposure EIT1, and the first readout operation RD1, and second image data may be generated by each pixel executing the second shutter operation SH2, the second time period exposure EIT2, and the second readout operation RD2. In an example embodiment, a resolution of the first image data may be higher than a resolution of the second image data.

In an example embodiment described with reference to FIG. 19, the first shutter operation SH1, the first time period exposure EIT1, the first readout operation RD1, the second shutter operation SH2, and the second time period exposure EIT2 may be similar to those described with reference to FIG. 5. For example, in each of the first shutter operation SH1 and the second shutter operation SH2, a reset operation of removing electric charges of the photodiode and the floating diffusion node of the pixel may be executed. During the first time period exposure EIT1 and the second time period exposure EIT2, the photodiode may be exposed to light and may generate electric charges.

The first readout operation RD1 may include first to fourth main readout operations MRD1-MRD4, and the first to fourth main readout operations MRD1-MRD4 may be the same as those described above with reference to FIGS. 10 to 15. The second readout operation RD2 may include first to fourth sub-readout operations SRD1-SRD4, and the first to third sub-readout operations SRD1-SRD3 may be executed in the same manner as the first to third main readout operations MRD1-MRD3. The fourth sub-readout operation SRD4 may be executed in a different manner from the fourth main readout operation MRD4.

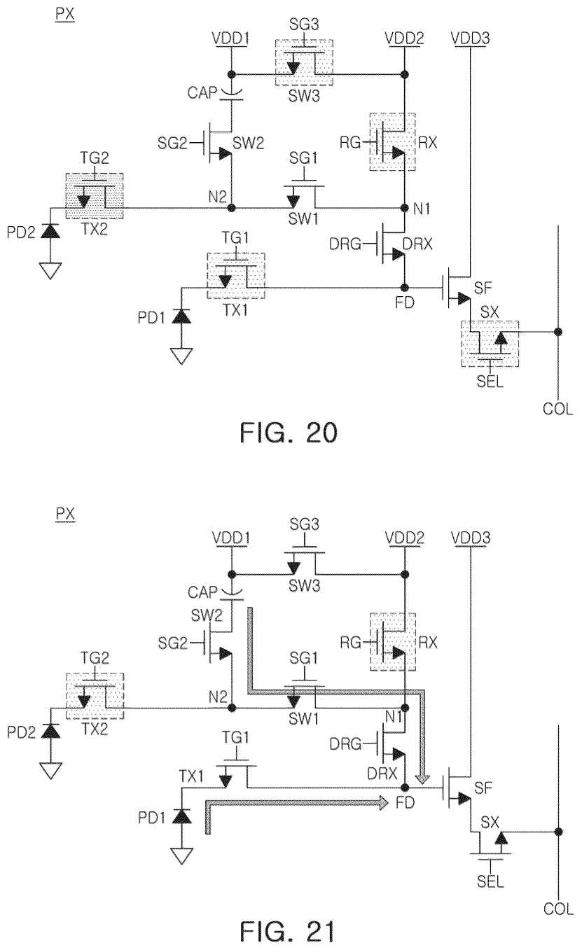

In an example embodiment, the fourth sub-readout operation SRD4 may be an operation of reading a signal from the pixel corresponding to electric charges that are generated to exceed the FWC of the first photodiode of the pixel during the second time period exposure EIT2 and that are stored in the capacitor. The first transfer transistor and the second transfer transistor may be controlled differently during the second time period exposure EIT2 such that electric charges generated to exceed the FWC of the first photodiode may be predominantly stored in the capacitor, which will be described in greater detail with reference to FIGS. 20 and 21.

In an example embodiment, in executing the plurality of sub-readout operations SRD1-SRD4, a number of times a pixel outputs a signal corresponding to electric charges generated by the first photodiode PD1 may be greater than a number of times a pixel outputs a signal corresponding to electric charges generated by the second photodiode PD2. Referring to FIG. 19, in executing the plurality of sub-readout operations SRD1-SRD4, a signal corresponding to electric charges generated by the first photodiode PD1 may be output from the first, second and fourth sub-readout operations SRD1, SRD2, and SRD4, and a signal corresponding to electric charges generated by the second photodiode PD2 may be output from the third sub-readout operation SRD3.

FIGS. 20 and 21 are diagrams illustrating operations of an image sensor according to some example embodiments.

FIG. 20 may be a diagram illustrating operation of the pixel PX during the second time period exposure EIT2 in an example embodiment described with reference to FIG. 19. FIG. 21 may be a diagram illustrating the fourth sub-readout operation SRD4 of the pixel PX in an example embodiment described with reference to FIG. 19.

First, referring to FIG. 20, during the second time period exposure EIT2, the first transfer transistor TX1, the second transfer transistor TX2, the third switch transistor SW3, and the reset transistor RX may be turned off. During the second time period exposure EIT2, the gain control transistor DRX, the first switch transistor SW1, and the second switch transistor SW2 may be turned on.

The first photodiode PD1 and the second photodiode PD2 may generate electric charges in response to light entering from the outside. The generated electric charge may not pass through the first transfer transistor TX1 and the second transfer transistor TX2 and may remain in the first photodiode PD1 and the second photodiode PD2. However, in an environment in which extremely strong light is input, a portion of electric charges generated by the first photodiode PD1 and the second photodiode PD2 may move.

For example, the voltage of a source of the first transfer transistor TX1 may decrease due to electric charges generated to exceed the FWC of the first photodiode PD1. Accordingly, even though the first transfer control signal TG1 input to a gate of the first transfer transistor TX1 is maintained at a voltage corresponding to a logic row, a path for electric charges movement may be formed through a channel of the first transfer transistor TX1. Electric charges having passed through the first transfer transistor TX1 may move to the capacitor CAP through the gain control transistor DRX, the first switch transistor SW1, and the second switch transistor SW2 and may be stored in the capacitor CAP.

In an example embodiment illustrated in FIG. 20, during the second time period exposure EIT2, the second transfer control signal TG2 may be configured as a voltage lower than the first transfer control signal TG1, and the second transfer transistor TX2 may be turned off more strongly than the first transfer transistor TX1. Accordingly, electric charges generated to exceed the FWC of the second photodiode PD may not pass over the second transfer transistor TX2, and electric charges transferred from the first photodiode PD1 may be predominantly stored in the capacitor CAP.

Thereafter, referring to FIG. 21, to execute the fourth sub-readout operation SRD4, the second transfer transistor TX2 and the reset transistor RX in the pixel PX may be turned off. Electric charges stored in the capacitor CAP may move to the floating diffusion node FD through the second node N2 and the first node N1, and the first transfer transistor TX1 may be turned on such that the residual electric charge remaining in the first photodiode PD1 may also move to the floating diffusion node FD. The amplification transistor SF may amplify a voltage of the floating diffusion node FD and may output a signal voltage to the column line COL.

In the fourth sub-readout operation SRD4, the reset voltage may be output to the column line COL after the signal voltage is output. When the signal voltage is output, before the reset voltage is output, a reset operation of removing electric charges of the floating diffusion node FD by turning on the reset transistor RX may be executed.

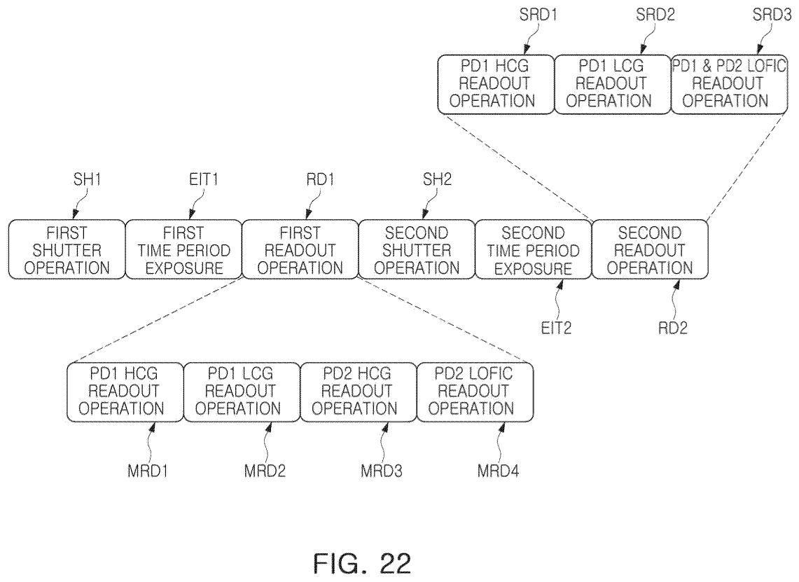

FIG. 22 is a diagram illustrating operations of an image sensor according to some example embodiments.

FIG. 22 may be a diagram illustrating operations of a pixel included in an image sensor according to an example embodiment. In an example embodiment illustrated in FIG. 22, operations of a pixel may include a first shutter operation SH1, a first time period exposure EIT1, a first readout operation RD1, a second shutter operation SH2, a second time period exposure EIT2 and a second readout operation RD2. The first time period exposure EIT1 and the second time period exposure EIT2 may be different, and for example, the first time period exposure EIT1 may be longer than the second time period exposure EIT2. First image data may be generated by each pixel executing the first shutter operation SH1, the first time period exposure EIT1 and the first readout operation RD1, and second image data may be generated by each pixel executing the second shutter operation SH2, the second time period exposure EIT2 and the second readout operation RD2.

In an example embodiment described with reference to FIG. 22, the first shutter operation SH1, the first time period exposure EIT1, the first readout operation RD1, the second shutter operation SH2 and the second time period exposure EIT2 may be similar to those described above with reference to FIG. 5. For example, in each of the first shutter operation SH1 and the second shutter operation SH2, a reset operation of removing electric charges of the photodiode and the floating diffusion node of the pixel may be executed. During the first time period exposure EIT1 and the second time period exposure EIT2, the photodiode may be exposed to light and may generate electric charge. The first readout operation RD1 may include first to fourth main readout operations MRD1-MRD4, and the first to fourth main readout operations MRD1-MRD4 may be the same as those described above with reference to FIGS. 10 to 15.

Referring to FIG. 22, the second readout operation RD2 may include first to third sub-readout operations SRD1-SRD4, and a number of times the pixel outputs a signal in the second readout operation RD2 may be less than a number of times the pixel outputs a signal in the first readout operation RD1. In an example embodiment illustrated in FIG. 22, the first sub-readout operation SRD1 may be an operation of reading a pixel signal corresponding to electric charges generated by the first photodiode PD1 under the condition in which the pixel has a relatively high conversion gain.

The second sub-readout operation SRD2 may be an operation of reading a pixel signal corresponding to electric charges generated by the first photodiode PD1 under the condition in which the pixel has a relatively low conversion gain. The third sub-readout operation SRD3 may be an operation of reading a pixel signal corresponding to electric charges generated to exceed a FWC in each of the first photodiode PD1 and the second photodiode PD2 and stored in a capacitor. As illustrated in FIG. 22, by configuring the sub-readout operations SRD1-SRD3 included in the second readout operation RD2, a signal-to-noise ratio of the low-light region may be increased such that a dynamic range may expand to the low-light region, and the signal-to-noise ratio in the light region in which a subject is represented may be improved.

In an example embodiment, in executing the plurality of sub-readout operations SRD1-SRD3, a number of times a pixel outputs a signal corresponding to electric charges generated by the first photodiode PD1 may be greater than a number of times a pixel outputs a signal corresponding to electric charges generated by the second photodiode PD2. Referring to FIG. 22, in executing the plurality of sub-readout operations SRD1-SRD3, a signal corresponding to electric charges generated by the first photodiode PD1 may be output in the first to third sub-readout operations SRD1-SRD3, and a signal corresponding to electric charges generated by the second photodiode PD2 may be output in the third sub-readout operation SRD3.

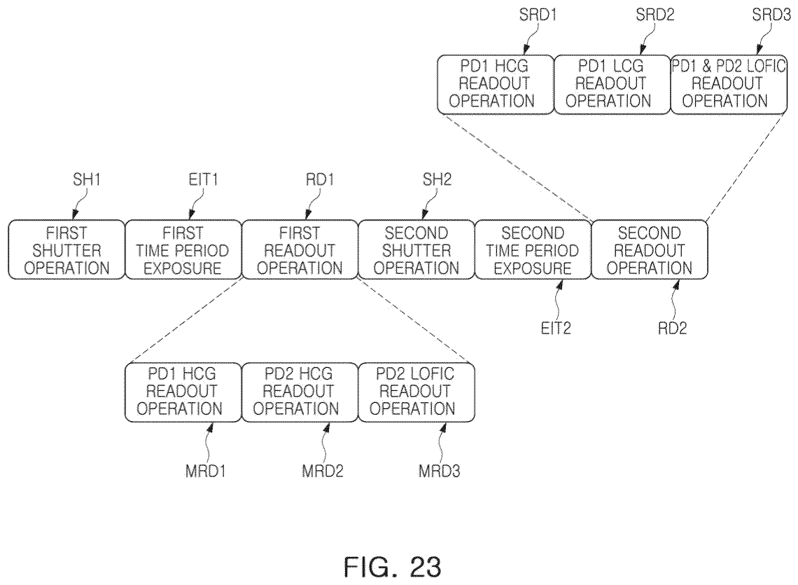

FIG. 23 is a diagram illustrating operations of an image sensor according to some example embodiments.

FIG. 23 may be a diagram illustrating operations of a pixel included in an image sensor according to FIGS. 1-4. In an example embodiment illustrated in FIG. 23, operations of a pixel may include a first shutter operation SH1, a first time period exposure EIT1, a first readout operation RD1, a second shutter operation SH2, a second time period exposure EIT2 and a second readout operation RD2. The first time period exposure EIT1 and the second time period exposure EIT2 may be different, and for example, the first time period exposure EIT1 may be longer than the second time period exposure EIT2. First image data may be generated by each of pixels executing the first shutter operation SH1, the first time period exposure EIT1 and the first readout operation RD1, and second image data may be generated by each of pixels executing the second shutter operation SH2, the second time period exposure EIT2 and the second readout operation RD2.

In an example embodiment described with reference to FIG. 23, the first shutter operation SH1, the first time period exposure EIT1, the second shutter operation SH2, the second time period exposure EIT2 and the second readout operation RD2 may be similar to those described above with reference to FIG. 22. However, in an example embodiment illustrated in FIG. 23, the first readout operation RD1 may include first to third main readout operations MRD1-MRD3. Accordingly, in the example embodiment illustrated in FIG. 23, a number of times a pixel outputs a signal in the first readout operation RD1 may be equal to a number of times a pixel outputs a signal in the second readout operation RD2.

Referring to FIG. 23, the first main readout operation MRD1 may be an operation of reading a pixel signal corresponding to electric charges generated by the first photodiode PD1 from a pixel under the condition in which the pixel has a relatively high conversion gain. According to an example embodiment, the first main readout operation MRD1 may be an operation of reading a pixel signal corresponding to electric charges generated by the first photodiode PD1 from a pixel under the condition in which the pixel has a relatively low conversion gain. The second main readout operation MRD2 may be an operation of reading a pixel signal corresponding to electric charges generated by the second photodiode PD2 from a pixel under the condition in which the pixel has a relatively high conversion gain. The third main readout operation MRD3 may be an operation of reading a pixel signal corresponding to electric charges generated to exceed a FWC in the second photodiode PD2 and stored in a capacitor.

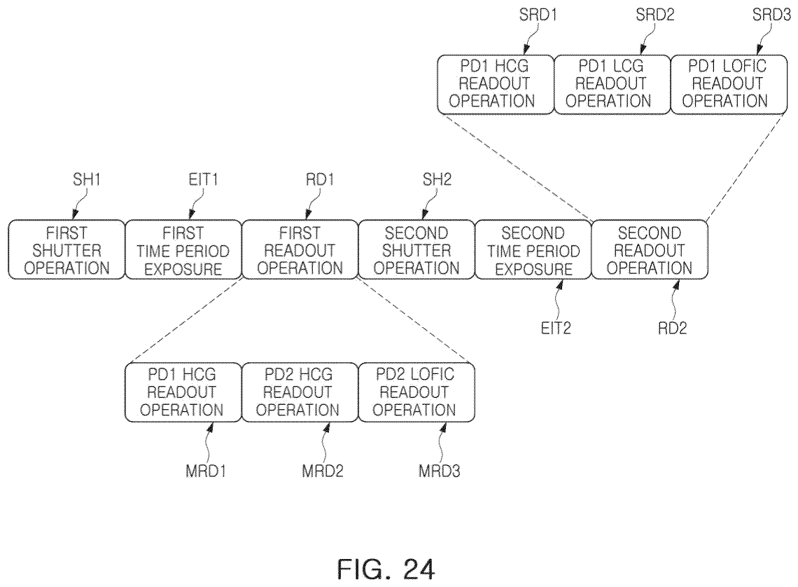

FIG. 24 is a diagram illustrating operation of an image sensor according to an example embodiment.

FIG. 24 may be a diagram illustrating operation of a pixel included in an image sensor according to FIGS. 1-4. The operation of the pixel may include a first shutter operation SH1, a first time period exposure EIT1, a first readout operation RD1, a second shutter operation SH2, a second time period exposure EIT2 and a second readout operation RD2. For example, the first time period exposure EIT1 may be longer than the second time period exposure EIT2. The first image data may be generated by each of pixels executing the first shutter operation SH1, the first time period exposure EIT1 and the first readout operation RD1, and the second image data may be generated by each of pixels executing the second shutter operation SH2, the second time period exposure EIT2 and the second readout operation RD2.

In an example embodiment described with reference to FIG. 24, the first shutter operation SH1, the first time period exposure EIT1, the first readout operation, the second shutter operation SH2, and the second time period exposure EIT2 may be similar to those described above with reference to FIG. 23. However, in the example embodiment illustrated in FIG. 24, the first to third sub-readout operations SRD1-SRD3 included in the second readout operation RD2 may be executed in different manners from the example embodiments described above. According to an example embodiment, differently from as illustrated in FIG. 24, the first main readout operation MRD1 may be an operation of reading a pixel signal corresponding to electric charges generated by the first photodiode PD1 from a pixel under the condition in which the pixel has a relatively low conversion gain.

Referring to FIG. 24, the first sub-readout operation SRD1 may be an operation of reading a pixel signal corresponding to electric charges generated by the first photodiode PD1 from a pixel under the condition in which the pixel has a relatively high conversion gain. The second sub-readout operation SRD2 may be an operation of reading a pixel signal corresponding to electric charges generated by the first photodiode PD1 from the pixel under the condition in which the pixel has a relatively low conversion gain. The third sub-readout operation SRD3 may be an operation of reading a pixel signal corresponding to electric charges generated by exceeding the FWC in the first photodiode PD1 and stored in the capacitor.

In the image sensor according to an example embodiment, the first readout operation may be executed after the first exposure time period, and the second readout operation may be executed after the second exposure time period. The first exposure time period may be longer than the second exposure time period, and the first image data may be generated by the first readout operation, and the second image data may be generated by the second readout operation. For example, the first image data may have a resolution higher than the second image data, and the second image data may be generated by applying binning to the pixel array.

In an example embodiment, differently from the first image data, the second image data may be generated only for a window of interest (WOI). The first image data may be generated based on a signal obtained by executing a first readout operation for each of a plurality of pixels included in the pixel array, whereas the second image data may be generated based on a signal obtained by executing a second readout operation for a portion of the plurality of pixels.

The first image data and the second image data may be used for different purposes. For example, when the image sensor is mounted on a means of transportation (e.g., a vehicle, etc.), the first image data may be used to accurately capture and recognize a flickering light source, and the second image data may be used to accurately capture and recognize a subject other than the flickering light source without distortion.

As described with reference to various example embodiments, the first readout operation and the second readout operation may be executed in different manners. For example, the first readout operation may include a plurality of main readout operations, and the second readout operation may include a plurality of sub-readout operations. When the number of the plurality of main readout operations and the number of the plurality of sub-readout operations are equal, at least one of the plurality of sub-readout operations may be executed in a different manner from the plurality of main readout operations. As an example, referring to FIG. 5, the fourth sub-readout operation SRD4 may be executed in a different manner from the first to fourth main readout operations MRD1-MRD4. As another example, referring to FIG. 23, the second sub-readout operation SRD2 and the third sub-readout operation SRD3 may be executed in a different manner from the first to third main readout operations MRD1-MRD3.

The number of a plurality of main readout operations and the number of a plurality of sub-readout operations may be different. As an example, referring to FIG. 22, a first readout operation RD1 may include first to fourth main readout operations MRD1-MRD4, and a second readout operation RD2 may include first to third sub-readout operations SRD1-SRD3. The third sub-readout operation SRD3 may be executed in a different manner from the first to fourth main readout operations MRD1-MRD4. By executing the first readout operation and the second readout operation in different manners considering a difference between the first exposure time period and the second exposure time period, a signal-to-noise ratio and a dynamic range of each of the first image data and the second image data may be improved.

According to the aforementioned example embodiments, each of the pixels may include a first photodiode, a second photodiode, and a pixel circuit, and the second photodiode may have a light-receiving area smaller than that of the first photodiode. By differently executing the first readout operation to obtain a pixel signal corresponding to electric charges generated by the first photodiode and the second photodiode during the first exposure time period and the second readout operation to obtain a pixel signal corresponding to electric charges generated by the first photodiode and the second photodiode during the second exposure time period, a signal-to-noise ratio, a dynamic range, and frames per second may be improved.

While the example embodiments have been illustrated and described above, it will be configured as apparent to those skilled in the art that modifications and variations may be made without departing from the scope of the present disclosure as defined by the appended claims.

What is claimed is:

1. An image sensor comprising:
a pixel array including a plurality of pixels arranged in a first direction and a second direction intersecting the first direction; and
a peripheral circuit connected to the plurality of pixels through a plurality of row lines and a plurality of column lines, the peripheral circuit configured to drive the plurality of pixels,
wherein each of the plurality of pixels includes a first photodiode, a second photodiode having a light-receiving area smaller than a light-receiving area of the first photodiode, and a pixel circuit connecting the first photodiode and the second photodiode to the peripheral circuit,
wherein the peripheral circuit is configured to obtain a first pixel signal by executing a first readout operation for each of the plurality of pixels after a first exposure time period, and to obtain a second pixel signal by executing a second readout operation for at least a portion of pixels of the plurality of pixels after a second exposure time period that is shorter than the first exposure time period, and
wherein the peripheral circuit is configured to generate first image data using the first pixel signal and second image data using the second pixel signal.

2. The image sensor of claim 1,
wherein the pixel circuit includes a floating diffusion node, a first transfer transistor connected between the floating diffusion node and the first photodiode, a second transfer transistor connected between the floating diffusion node and the second photodiode, and a gain control transistor connected to the floating diffusion node, and
wherein the peripheral circuit is configured to select a high conversion gain condition by turning off the gain control transistor and to select a low conversion gain condition by turning on the gain control transistor.

3. The image sensor of claim 2, wherein the pixel circuit comprises a capacitor, and
wherein, in the first readout operation, each of the plurality of pixels is configured to output a voltage corresponding to electric charges generated by the first photodiode under the high conversion gain condition and the low conversion gain condition in sequence, to output a voltage corresponding to electric charges generated by the second photodiode under the high conversion gain condition, and to output a voltage corresponding to electric charges that are generated by the second photodiode and that are stored in the capacitor of the pixel circuit.

4. The image sensor of claim 3, wherein, in the second readout operation, each of the at least a portion of pixels is configured to output a voltage corresponding to electric charges generated by the first photodiode under the high conversion gain condition and the low conversion gain condition in sequence, to output a voltage corresponding to electric charges generated by the second photodiode under the high conversion gain condition, and to output a voltage corresponding to electric charges that are generated by the first photodiode and the second photodiode and that are stored in the capacitor.

5. The image sensor of claim 3, wherein, in the second readout operation, each of the at least a portion of pixels is configured to output a voltage corresponding to electric charges generated by the first photodiode under the high conversion gain condition and the low conversion gain condition in sequence, to output a voltage corresponding to electric charges generated by the second photodiode under the high conversion gain condition, and to output a voltage corresponding to electric charges that are generated by the first photodiode and that are stored in the capacitor.

6. The image sensor of claim 3, wherein, in the second readout operation, each of the at least a portion of pixels is configured to output a voltage corresponding to electric charges generated by the first photodiode under the high conversion gain condition and the low conversion gain condition in sequence, and to output a voltage corresponding to electric charges that are generated by the first photodiode and that are stored in the capacitor.

7. The image sensor of claim 3, wherein, in the second readout operation, each of the at least a portion of pixels is configured to output a voltage corresponding to electric charges generated by the first photodiode under the high conversion gain condition and the low conversion gain condition in sequence, and to output a voltage corresponding to electric charges that are generated by the first photodiode and the second photodiode and that are stored in the capacitor.

8. The image sensor of claim 1, wherein, in the first readout operation, each of the plurality of pixels is configured to output a voltage corresponding to electric charges generated by the first photodiode under one of a high conversion gain condition or a low conversion gain condition, to output a voltage corresponding to electric charges generated by the second photodiode under the high conversion gain condition, and to output a voltage corresponding to electric charges that are generated by the second photodiode and that are stored in a capacitor of the pixel circuit.

9. The image sensor of claim 8, wherein, in the second readout operation, each of the at least a portion of pixels is configured to output a voltage corresponding to electric charges generated by the first photodiode under the high conversion gain condition and the low conversion gain condition in sequence, and to output a voltage corresponding to electric charges that are generated by the first photodiode and the second photodiode and that are stored in the capacitor of the pixel circuit.

10. The image sensor of claim 8, wherein, in the second readout operation, each of the at least a portion of pixels is configured to output a voltage corresponding to electric charges generated by the first photodiode under the high conversion gain condition and the low conversion gain condition in sequence, and to output a voltage corresponding to electric charges that are generated by the first photodiode and that are stored in the capacitor of the pixel circuit.

11. The image sensor of claim 1, wherein a frame rate of the first image data is lower than a frame rate of the second image data.

12. The image sensor of claim 1, wherein a resolution of the first image data is higher than a resolution of the second image data.

13. An image sensor comprising:
a plurality of pixels, each including a first photodiode, a second photodiode having a light-receiving area smaller than a light-receiving area of the first photodiode, and a pixel circuit connected to the first photodiode and the second photodiode; and
a peripheral circuit configured to execute a first shutter operation, a first time period exposure operation, a first readout operation, a second shutter operation, a second time period exposure operation, and a second readout operation for each of the plurality of pixels in sequence,
wherein the first readout operation includes a plurality of first type readout operations executed in sequence, and the second readout operation includes a plurality of second type readout operations executed in sequence, and
wherein the peripheral circuit is configured to execute at least one of the plurality of sub-readout operations differently from the plurality of main readout operations.

14. The image sensor of claim 13,
wherein the first readout operation includes a first type readout operation, a second first type readout operation, a third first type readout operation, and a fourth first type readout operation, and the second readout operation includes a first second type readout operation, a second type readout operation, a third second type readout operation, and a fourth second type readout operation, and
wherein the peripheral circuit is configured to execute the fourth second type readout operation differently from each of the first type readout operation, the second first type readout operation, the third first type readout operation, and the fourth first type readout operation.

15. The image sensor of claim 13,
wherein the first readout operation includes a first type readout operation, a second first type readout operation, and a third first type readout operation, and the second readout operation includes a first second type readout operation, a second type readout operation, and a third second type readout operation, and
wherein the peripheral circuit is configured to execute the third second type readout operation differently from each of the first type readout operation, the second first type readout operation, and the third first type readout operation.

16. The image sensor of claim 15, wherein the peripheral circuit is configured to execute the second type readout operation differently from each of the first type readout operation, the second first type readout operation, and the third first type readout operation.

17. The image sensor of claim 13,
wherein the first readout operation includes a first type readout operation, a second first type readout operation, a third first type readout operation, and a fourth first type readout operation, and the second readout operation includes a first second type readout operation, a second type readout operation, and a third second type readout operation, and
wherein the peripheral circuit is configured to execute the third second type readout operation differently from the each of the first type readout operation, the second first type readout operation, the third first type readout operation, and the fourth first type readout operation.

18. The image sensor of claim 13,
wherein each of the plurality of pixels includes a capacitor, and
wherein a last second type readout operation lastly executed among the plurality of second type readout operations is configured to be executed differently from the plurality of first type readout operations, and the last second type readout operation is an operation of reading a signal corresponding to electric charges that are generated by at least one of the first photodiode and the second photodiode and that are stored in the capacitor during the second time period exposure operation.

19. An image sensor comprising:
a plurality of pixels, each including a first photodiode, a second photodiode having a light-receiving area smaller than a light-receiving area of the first photodiode, and a pixel circuit connected to the first photodiode and the second photodiode; and
a peripheral circuit configured to drive the plurality of pixels,
wherein the pixel circuit is configured to output a signal by executing a plurality of first type readout operations after a first exposure time period, and to output a signal by executing a plurality of second type readout operations after a second exposure time period that is shorter than the first exposure time period, and
wherein, in the plurality of second type readout operations, a number of times the pixel circuit outputs a signal corresponding to electric charges generated by the first photodiode is greater than a number of times the pixel circuit outputs a signal corresponding to electric charges generated by the second photodiode.

20. The image sensor of claim 19, wherein a number of the plurality of second type readout operations is equal to or less than a number of the plurality of first type readout operations.
